(19) United States
(12) Patent Application Publication
(10) Pub. No.: US 2012/0126273 A1
(43) Pub. Date: May 24, 2012

(54) OLED SUBSTRATE CONSISTING OF TRANSPARENT CONDUCTIVE OXIDE (TCO) AND ANTI-IRIDESCENT UNDERCOAT

(75) Inventors: Roman Y. Korotkov, Boothwyn, PA (US); Ryan C. Smith, Schwenksville, PA (US); Gary S. Silverman, Chadds Ford, PA (US); Jeffery L. Stricker, Narberth, PA (US); Stephen W. Carson, Coatesville, PA (US)

(73) Assignee: Arkema Inc., Philadelphia, PA (US)

(21) Appl. No.: 13/381,417

(22) PCT Filed: Jul. 1, 2010
(86) PCT No.: PCT/US10/40715

§ 371 Date: Feb. 2, 2012

Related U.S. Application Data
(60) Provisional application No. 61/223,150, filed on Jul. 6, 2009.

(51) Int. Cl. H01L 51/50; H01L 51/40

(52) U.S. Cl. 257/98; 438/29; 257/E33.073; 257/E51.018; 257/40

(57) ABSTRACT

A light-emitting devices and methods for forming light-emitting devices are provided. The device comprises of a substrate having a first refractive index, a transparent electrode that is coupled to an organic layer, where the transparent electrode has a second refractive index different from the first refractive index. An undercoat layer is selected that has a third refractive index to substantially match the first refractive index to the second refractive index. The undercoat layer is selected such that it has a capacity to reduce root mean square roughness of the transparent electrode film deposited. The undercoat layer is selected to improve electrical properties of the transparent electrode layer. The undercoat layer is provided between the substrate and the transparent electrode.

### FIELD OF THE INVENTION

The present invention relates generally to light-emitting devices and, more particularly, to organic light emitting devices (OLEDs) and methods of forming OLEDs that include providing an undercoat layer between a substrate and a transparent conductive electrode (TCO) to reduce reflection of the glass and TCO interface and improve conductivity of the TCO layer.

### BACKGROUND OF THE INVENTION

Light emitting diodes (LEDs) are known and are used in many applications, such as in displays and status indicators. LEDs may be formed from organic and/or inorganic materials. Inorganic LEDs include an inorganic light emitting material for a light emitting layer, typically an inorganic semiconductor material such as gallium arsenide. Organic LEDs (OLEDs) typically include an organic polymer material for the light emitting layer. Inorganic LEDs may provide bright and durable point light sources, whereas OLEDs may provide large area surface emitting light sources.

Organic light emitting diodes (OLEDs) have a potential for providing an inexpensive alternative to light emitting diodes (LEDs). OLEDs generally include thin organic layers, either polymers or small molecules, sandwiched between a pair of electrodes. Typically, at least one of the electrodes is transparent to the emitted light. Light emission out of the device, however, may be reduced due to internal reflection of light within the various layers of the OLED device. This effect is known as waveguiding. FIG. 1a shows the schematic diagram of the propagation of emitted light inside an OLED device. The refractive indexes for the hole transport layer (HTL) and Electro-luminescent (EL) layers comprising the device are also presented in this figure. The total amount of light lost in this structure of 80% comprises the substrate waveguide mode loss (30%) and TCO/organic waveguide mode loss (50%). This loss phenomenon is associated with total internal reflectance (TIR) occurring at the air/glass and the glass/TCO interfaces. Under these conditions the angle of refraction (Θ) is greater than that of the incidence. On increasing the incident angle further, the refractive ray grazes the substrate and this angle is called critical angle (Θ_{c}) (FIG. 1a).

To improve light outcoupling out of the OLED structure several approaches have been proposed in the literature. For example, a utilization of micro-lenses on the backside of the glass substrate surface was shown to improve light outcoupling (J. Lim et al., Opt. Exp. 14 (2006) 6564). The formation of a mono-layer of silica micro-spheres (K. Neyts, et al., J. Opt. Soc. Am. A 23 (2006) 1201), the use of high refractive index substrate, low refractive index silica-aerogel and MgF₂ antireflection coatings was shown to improve light outcoupling (K. Saxena et al., J. Lum. 128 (2008) 525).

### SUMMARY OF THE INVENTION

The present invention is embodied in a method for forming a light-emitting device. The method provides a substrate having a first refractive index. The method also couples a transparent electrode to an organic layer, where the transparent electrode has a second refractive index different from the first refractive index. The method further selects an undercoat layer having a third refractive index to substantially match the first refractive index to the second refractive index.

The present invention is also embodied in a light-emitting device. The light-emitting device includes a substrate having a first refractive index. The light-emitting device also includes a transparent electrode coupled to an organic layer and disposed between the organic layer and the substrate. The transparent electrode has a second refractive index that is different from the first refractive index. The light-emitting device also includes an undercoat layer disposed between the substrate and the transparent electrode, where the undercoat layer has a third refractive index. The undercoat layer is formed with the third refractive index such that the first refractive index is substantially matched to the second refractive index.

The present invention is also embodied in a method for fabricating a light-emitting device. The method forms an undercoat layer on a substrate by a chemical vapor deposition (CVD) process, forms a transparent electrode (TCO) on the undercoat layer by the CVD process and forms an organic layer on the transparent electrode. The substrate has a first refractive index and the transparent electrode has a second refractive index that lies between the refractive indexes of the substrate and TCO. The undercoat layer is formed to have a third refractive index such that the first refractive index is substantially matched to the second refractive index.

The method of the present invention reduces the glass/TCO loss mode by incorporation of the additional layer with a refractive index in between those of the TCO and the substrate. The refractive index and thickness of the additional layer is carefully selected to reduce glass/TCO waveguiding mode. For effective cancellation of the glass/TCO mode, the refractive index of the undercoat layer is (n₁×n₃)^{1/2}˜1.69, where n₁ and n₃ are the refractive indexes of glass and TCO respectively. The thickness of the undercoat layer is d=(λ/4)/n₂˜63 nm where λ and n₂ are wavelength of light and refractive index of the undercoat.

### BRIEF DESCRIPTION OF THE DRAWINGS

The invention may be understood from the following detailed description when read in connection with the accompanying drawings. It is emphasized that, according to common practice, various features of the drawings may not be drawn to scale. On the contrary, the dimensions of the various features may be arbitrarily expanded or reduced for clarity. Moreover, in the drawing, common numerical references are used to represent like features. Included in the drawing are the following figures:

FIG. 1a is schematic diagram of an OLED structure with propagation of the emitted light via various modes depicted.

FIG. 1b is a schematic diagram of an OLED structure with an undercoat layer structure in accordance with the present invention, with propagation of the emitted light via various modes depicted. The opposite polarizations of the light reflected from glass/TCO and TCO/organic interfaces is shown with heavy arrows.

FIG. 2 is a block diagram of an exemplary light-emitting device, according to an aspect of the present invention.

FIG. 3 is a flow chart illustrating an exemplary method for forming an undercoat layer shown in FIG. 2, according to an aspect of the present invention.

FIG. 4 is a flow chart illustrating an exemplary method for fabricating a light-emitting device, according to an aspect of the present invention.

FIG. 5 is a graph of transmittance versus wavelength of AZO/borosilicate and AZO/Al2O3/borosilicate samples.

FIG. 6 is a graph of transmittance versus wavelength of AZO/borosilicate and AZO/Al₂O₃/borosilicate samples.

FIG. 7 is a graph of reflectance versus wavelength of the AZO/borosilicate and AZO/Al₂O₃/borosilicate samples.

### DETAILED DESCRIPTION OF THE INVENTION

As a general overview, aspects of the present invention relate to a light-emitting device and methods for forming a light-emitting device. The light-emitting device includes an organic layer that is formed between electrodes and is supported by a transparent substrate. One of the electrodes is desirably transparent and is formed proximate to the substrate. The substrate and transparent electrode have different refractive indices which may reduce transmission of light (emitted by the organic material) out of the substrate. According to aspects of the present invention, an undercoat layer is provided between the substrate and the transparent electrode. The undercoat layer desirably matches the refractive index of the substrate to the refractive index of the transparent electrode. The undercoat layer, thus, reduces the reflection of emitted light within the light-emitting device, thereby increasing the transmission of light out of the device.

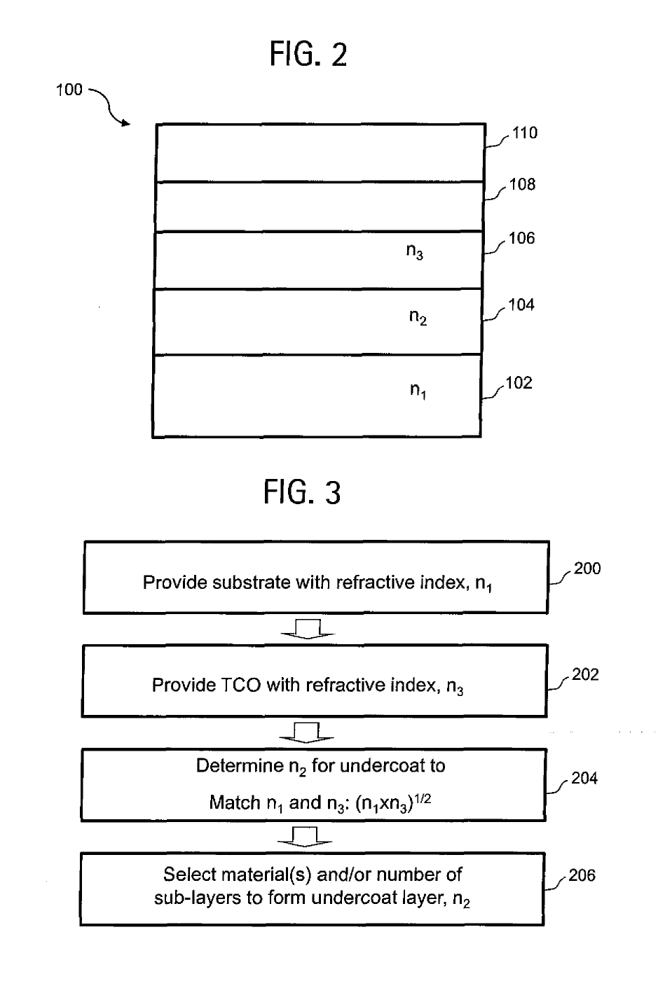

Referring to FIG. 2, an exemplary light-emitting device 100 is shown. Light-emitting device 100 includes organic layer 108 and is supported by transparent substrate 102. Light-emitting device 100 also includes electrodes 106 and 110 with organic layer 108 positioned there between. Electrode 106 is desirably transparent (referred to herein as transparent electrode 106) and is positioned between substrate 102 and organic layer 108. Undercoat layer 104 is positioned between transparent electrode 106 and substrate 102. Light-emitting device 100 may include OLED or photovoltaic devices.

During operation of light-emitting device 100, current flows from one electrode to the other and light is emitted from organic layer 108, for example, in a direction towards substrate 102. Light that is not reflected by an interface between transparent electrode 106 and substrate 102 is transmitted through substrate 102 and out of light-emitting device 100.

Substrate 102 has a first refractive index (n₁) whereas transparent electrode 106 has a second refractive index (n₃) that is typically different from n₁. For example, n₁ is typically between about 1.45 and about 1.55 and n₃ is typically between about 1.80 and about 1.95. As known to the skilled person, because refractive indices n₁, n₃ may be different, a portion of light emitted by organic layer 108 may be reflected back into transparent electrode 106, rather than transmitted into substrate 102. Accordingly, transmission of light out of device 100 may be reduced.

For a conventional OLED (i.e. with no undercoat layer 104 present), about 50% of emitted light may be internally reflected within the organic layer and about 30% of light may be reflected at the interface between the transparent electrode and the substrate. Accordingly, only about 20% of light is typically transmitted out of a conventional OLED. For example, it is typically difficult for a conventional OLED formed with indium tin oxide (ITO) as its transparent electrode to transmit blue light, due to the absorption of ITO in the blue light region. Thus, this conventional OLED typically uses an increased power in order to sufficiently transmit blue light out of the OLED. If more light is transmitted out of the transparent electrode, the power provided to the OLED may be reduced.

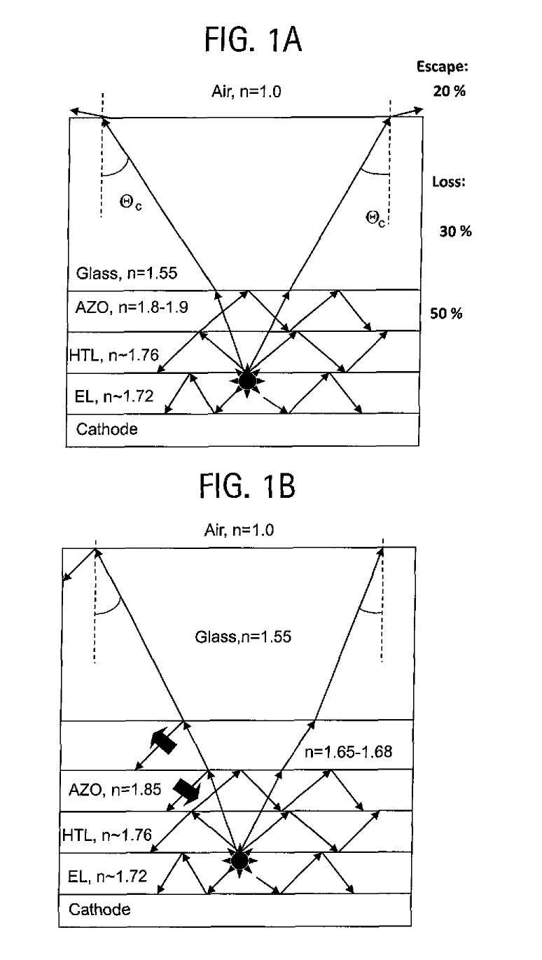

Undercoat layer 104 having a third refractive index (n₂) may be provided between transparent electrode 106 and substrate 102. Undercoat layer 104 desirably substantially matches n₁ to n₃, in order to reduce reflection within transparent electrode 106. In an exemplary embodiment, n₂ is between about 1.60 and about 1.96. Undercoat layer 104 may be formed from an anti-reflection coating. As known to the skilled person, an anti-reflection coating may be formed, based on n₁, n₃, with refractive index of n₂=(n₁×n₃)^{1/2}, and a thickness of the undercoat layer 104 of (λ/4)/n₂, to suppress the TCO/organic wave-guided mode over one wavelength or over a range of wavelengths. In this case, the relative phase-shift between the wave reflected from the glass/TCO and the TCO/organic interfaces is 180 degrees (FIG. 1b). Hence, the destructive interference between the two reflected waves suppresses the TCO wave-guided mode. By providing substantially minimum reflectance, light may be transmitted from transparent electrode 106 to substrate 102 with minimal reflection of light within transparent electrode 106. Accordingly, light transmission out of device 100 may be increased.

Undercoat layer 104 may be formed from one or more sub-layers, in order to produce a material having third refractive index n₂. In general, undercoat layer 104 may be selected from one or more materials and a number of sub-layers dependent upon a variety of factors, such as the material of substrate 102, the material of transparent electrode 106, the material of organic layer 108, the desired wavelength region for the emitted light, performance factors of device 100 and/or a desired cost. Accordingly, a number of materials or combinations thereof, with various refractive indices, may be formed into a number of sub-layers in order to produce undercoat layer 104 with a refractive index (i.e., n₂) that matches n₁ to n₃. Although in an exemplary embodiment between about one to seven sub-layers is used to produce undercoat layer 104, it is understood that any suitable number of sub-layers may be used to produce refractive index n₂. Selection of undercoat layer 104 is described further below with respect to FIG. 2.

A description of an undercoat layer to produce a desired refractive index n₂ is described in U.S. Pat. No. 5,401,305 to Russo et al., entitled “Coating Composition for Glass,” the contents of which are incorporated herein by reference for their teaching of undercoat materials and formation of an undercoat layer having a specific refractive index and anti-iridescence. According to one embodiment, undercoat layer 104 may be formed from one or more sub-layers of a combination of tin oxide and silicon dioxide. An another embodiment, tin oxide may be replaced in the sub-layers entirely, or in part, by oxides of other metals such as, for example, germanium, titanium, aluminum, zirconium, zinc, indium, cadmium, hafnium, tungsten, vanadium, chromium, molybdenum, iridium, nickel and tantalum. It is understood that undercoat layer 104 may be formed from any suitable material to produce a refractive index n₂ to match n₁ to n₃. Examples of materials for undercoat layer 104 include oxides, but are not limited to, silicon oxide, titanium oxide, tin oxide, zinc oxide, aluminum oxide or any combination thereof.

Depending upon the thickness of transparent electrode 106, various reflected colors (i.e., wavelengths of light) may be observed via substrate 102. The iridescence is generally due to an interference phenomenon where certain wavelengths of light reflected from one side of a coating layer are out of phase with light at the same wavelengths that are reflected from an opposite side of the coating layer. This iridescence effect is generally considered to be detrimental to the appearance of light-emitting device 100 in applications such as for a display. According to another embodiment of the present invention, undercoat layer 104 may be formed to reduce or eliminate any iridescence of various wavelengths of light reflected by transparent electrode 106 in the direction of substrate 102. For example, undercoat layer 104 may be formed with a quarter wavelength (or half wavelength) optical thickness, where optical thickness refers to the thickness of undercoat layer 104 multiplied by its refractive index (n₂), to cancel the interfering wavelengths. Other examples of minimizing or eliminating iridescence are described in U.S. Pat. No. 5,401,305 to Russo et al. It is understood that undercoat layer 104 may be formed to minimize or eliminate iridescence by any suitable method.

Although organic layer 108 is illustrated as one layer, organic layer 108 may include one or more organic layers. In addition, organic layer 108 may include a hole transport layer coupled to transparent electrode 106, a light emissive layer and an electron injecting layer coupled to electrode 110. When an appropriate voltage is applied to organic layer 108, the injected positive and negative charges recombine in the emissive layer to produce light. The emissive layer may include, but is not limited to blue, red and/or green emitting organic materials. The structure of organic layer 108 and selection of electrodes 106, 110 are desirably selected to maximize the recombination process in the emissive layer, thus maximizing the light output from light-emitting device 100. In general, organic layer 108 may be formed with any suitable organic material. For example, materials for organic layer 108 may include, but are not limited to, polymers, small molecules and oligomers.

In general, transparent electrode 106 is formed from a transparent conducting oxide (TCO). In an exemplary embodiment, transparent electrode 106 is formed from doped zinc oxide. Transparent electrode 106 may be formed from any suitable transparent conducting oxide, for example, ITO, indium zinc oxide (IZO), F-doped tin oxide and niobium-doped titanium dioxide. Electrode 110 may be formed from any suitable conductive metal material, such as, but not limited to aluminum, copper, silver, magnesium or calcium.

Substrate 102 may be formed of any suitable transparent material for transmitting light from organic layer 108 through substrate 102 in a desired wavelength range. Material for substrate 102 may include, but is not limited to, soda lime glass including soda lime float glass and low-iron soda lime glass; borosilicate glass; and flat panel glass.

Undercoat layer 104 may be formed to minimize ion migration from substrate 102 into transparent electrode 106. For example, if substrate 102 may be formed from soda lime glass as opposed to flat panel glass. Soda lime glass, however, typically includes a larger concentration of sodium ions that may diffuse into transparent electrode 106 and cause haze formation and/or holes in transparent electrode 106 (which may result in electrical connectivity problems). It is known that silicon dioxide may effectively block the sodium ion migration. Accordingly, if undercoat layer 104 includes silicon dioxide, sodium ion migration into transparent electrode 106 may be prevented.

Undercoat layer 104 improves the electrical properties of the TCO layer 106. For example, when AZO films, such as Al₂O₃, are deposited on amorphous substrates (glass) the resistivity of the AZO films was found to decrease.

Referring next to FIGS. 2 and 3, a flow chart illustrating an exemplary method for forming undercoat layer 104 is shown. At step 200, substrate 102 is provided with first refractive index n₁. At step 202, transparent electrode 106 is provided with second refractive index n₃. For example, transparent electrode 106 may be selected to be suitable for organic layer 108 and substrate 102 may be selected to have suitable transparency in a desired wavelength range. Refractive indices n₁, n₃ for respective materials of substrate 102 and transparent electrode 106 are generally well known (FIG. 1a-b). The refractive index of a material may also be determined by conventional methods known to those of skill in the art.

At step 204, third refractive index n₂ is determined such that refractive indices n₁ and n₃ may be substantially matched to each other. At step 206, one or more materials (or combinations of materials), as well as a number of sub-layers for undercoat layer 102 are selected based on n₃ determined at step 204. Although steps 204 and 206 are illustrated as being performed sequentially, it is understood that steps 204 and 206 may be performed simultaneously. For example, the combination of materials and sub-layers may be adjusted until n₂ is determined that matches n₁ to n₃.

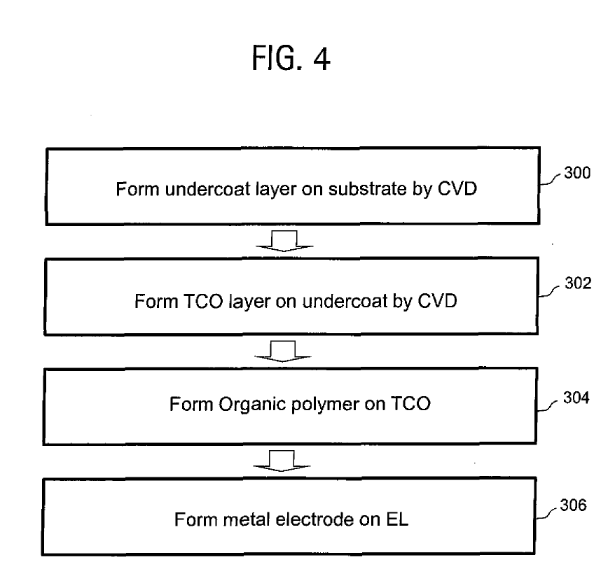

Referring next to FIGS. 2 and 4, a method for fabricating a light-emitting device is shown. At step 300, undercoat layer 104 is formed on substrate 102 by a chemical vapor deposition (CVD) process. An example of the fabrication process for undercoat layer 104 is provided in U.S. Pat. No. 5,401,305 to Russo et al. According to an embodiment of the present invention, the CVD process is performed at atmospheric pressure and at a temperature of less than about 400° Celsius (C), more particularly less then about 350° C. According to another embodiment, the CVD process may be performed at atmospheric pressure and a temperature of 300° C. to 650° C. Undercoat layer 104 may be formed by the CVD process for each of a number of sub-layers. Each sub-layer may be deposited with a suitable material and respective thickness in order to produce the total undercoat layer 104 with third refractive index n₂. Although undercoat layer 104 is described as being formed using a CVD process, it is understood that undercoat layer 104 may be formed on substrate 102 by any suitable process, for example, by a sputtering process or by a pulsed laser deposition (PLD) process.

At step 302, transparent electrode 106 is formed on undercoat layer 104, also by a CVD process. Although in one embodiment, the CVD process for transparent electrode 106 is performed at atmospheric pressure and at a temperature of about 400° C., the CVD process for transparent electrode 106 may be performed at a temperature of 300° C. to 650° C. It is contemplated that depositing transparent electrode 106 using the CVD process, as compared to a sputtering process, may reduce a surface roughness of transparent electrode 106. For example, organic layer 108 may be very thin, for example, about 10 nm thick. If transparent electrode 106 includes a rough surface, one or more portions of organic layer 108 may be too thin to provide suitable charge mobility, thus shorting device 100 between electrodes 106, 110.

At step 304, organic layer 108 is formed on transparent electrode 106. Organic layer 108 may be formed, by any suitable process, by depositing a hole transport layer on transparent electrode 106, a light emissive layer on the hole transport layer and an electron injecting layer on the light emitting layer. As one example, organic layer 108 may be formed by a vacuum evaporation process. At step 306, metal electrode 110 is formed on organic layer 108, for example, on the electron injecting layer of organic layer 108. Metal electrode 110 may be formed by any suitable process, for example, by a vacuum evaporation process or by a sputtering process.

### EXAMPLES

### Example 1

A gas mixture of 1.2 mol % of ZnMe₂-MeTHF in 11 sLpm of nitrogen carrier gas was fed into a primary feed tube at 160° C. A dopant was introduced into the primary feed tube from a stainless steel bubbler. The bubbler contained AlMe₂acac dopant at 66° C. Al-precursor was picked up by nitrogen, preheated to 70° C., with a flow rate of 310 seem. Oxidants were introduced into a secondary feed tube through two stainless steel bubblers. The first and second bubblers contained H₂O and 2-propanol at 60 and 65° C., respectively. H₂O was picked up by nitrogen, preheated to 65° C., with the flow rate of 400 sccm. 2-Propanol was picked up by nitrogen, preheated to 70° C., with the flow rate of 600 sccm. The secondary feeds were co-fed with the primary flow inside a mixing chamber. The mixing chamber was 1¼ inch in length, corresponding to a mixing time of 250 msec between the primary and secondary feed streams. The substrate used for the deposition was borosilicate glass with the thickness of 0.7 mm. The substrate was heated on a resistively heated nickel block set at 550° C. The deposition time for these films was 55 seconds in a static mode, and the resulting ZnO films had a thickness of 725 nm, for a deposition rate of 13.2 nm/s. The sheet resistance for the films was measured using an automated 4-point probe scanning station. The average sheet resistance data is presented in Table 1 is the average sheet resistances across a 14×14 data matrix measured on a 6×6 inch wafer. The transmittance and reflectance spectra were obtained using a Lambda 950 spectrophotometer. In all spectra the zeroing of the instrument was done with air ambient.

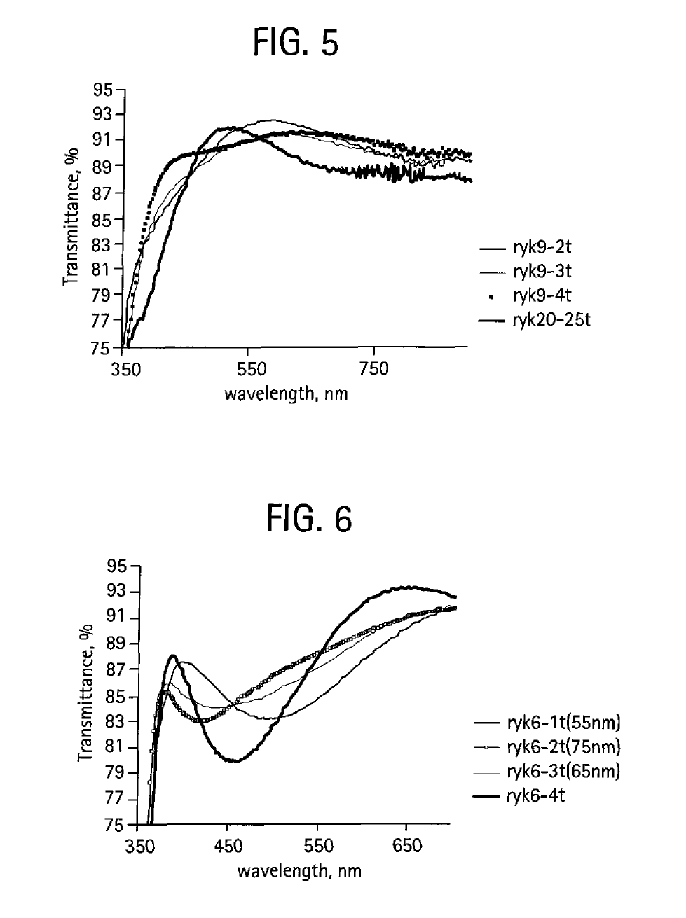

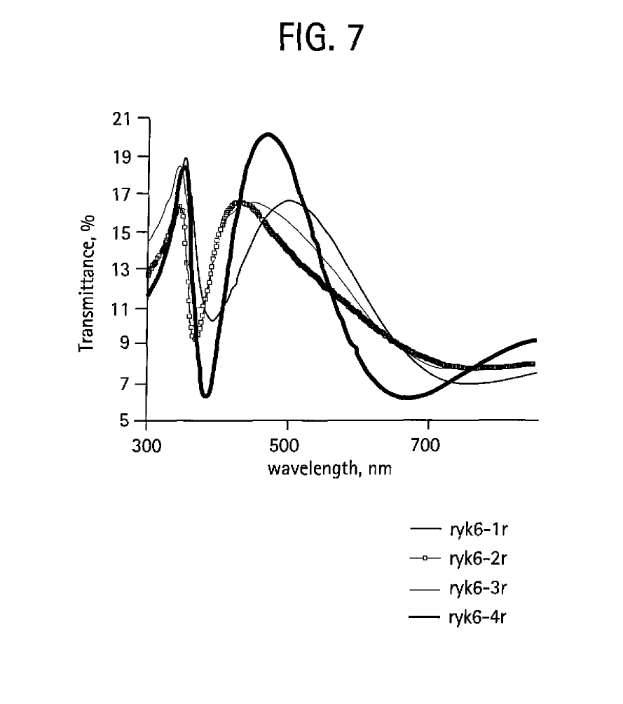

Transmittance curves for a set of samples are shown in FIG. 5. The transmittance curve for the AZO samples with 55 nm (Ryk9-2), 65 nm (Ryk9-3) and 75 nm (Ryk9-4) thick Al₂O₃ undercoats are shown. For comparison, the transmittance curve for the AZO/glass sample without undercoat is shown (Ryk20-25t). The AZO layer thickness is 145 nm for all structures. The considerable increase in (350-450) transmittance nm is visible in FIG. 5. The reduction in the sheet resistance of 28% is shown in Table 1.

TABLE 1
Thickness and electrical properties for the AZO/undercoat/
borosilicate stacks.

| # | Al₂O₃, nm | AZO | SR, Ω/sq |
|---|---|---|---|
| Ryk20-25 | none | 145 ± 5 | 23.2 |
| Ryk9-2 | 55 | 145 ± 5 | 16.41 |
| Ryk9-3 | 65 | 145 ± 5 | 16.87 |
| Ryk9-4 | 75 | 145 ± 6 | 16.84 |

### Example 2

The transmittance curves for the glass/Al₂O₃/AZO films with 55 (Ryk6-1), 65 (Ryk6-3) and 75 (Ryk6-2) nm thick undercoats are presented in FIG. 6. The AZO film thickness was 175 nm (Tablet). The iridescent color of the coatings is greatly reduced by utilization of the undercoat. The variation in the visible reflectance for the AZO samples without undercoat is 79.5 to 88%. This variation represents 9.6% difference in the visible transmittance from the valley to the peak. The variation in the visible reflectance for the glass/Al₂O₃/AZO structures is reduced to 2.3%. This flattening of the transmittance curve is due to dramatic decrease of the reflectance (FIG. 6).

The sheet resistance of the coatings with Al₂O₃ undercoat is reduced by 15 as compared to the structures without undercoat is shown in Table 2.

TABLE 2
Thickness and electrical properties for the
AZO/undercoat/borosilicate stacks.

| # | Al₂O₃, nm | AZO | SR, Ω/sq |
|---|---|---|---|
| Ryk6-4 | none | 175 ± 4 | 18.3 ± 1.6 |
| Ryk6-1 | 55 | 175 ± 5 | 15.02 ± 0.99 |
| Ryk6-2 | 75 | 175 ± 6 | 15.80 ± 0.72 |
| Ryk6-3 | 65 | 175 ± 6 | 15.7 ± 0.81 |

### Example 3

Al₂O₃ layers (65 nm) thick were deposited on borosilicate glass substrates. AZO films, 165 nm thick were deposited on top of glass/Al₂O₃ undercoats. OLED devices were fabricated under similar conditions for all samples presented in Table 3 on top of glass/AZO/HIL and glass/Al₂O₃/AZO/HIL stacks. The external quantum efficiencies (EQE) were calculated for substrates with and without undercoats (Table 3). The devices were manufactured with organic hole injection layers (HIL) deposited on top of the AZO films. The increase of the OLED efficiency of 9.1-11.6% is shown in Table 3.

TABLE 3
Turn on voltage (V), external quantum efficiency (EQE) and the calculated
increase of the EQE with Al₂O₃ undercoat layer and without.

| | HIL, nm | V, Volts | EQE, % | % Increase |
|---|---|---|---|---|
| Glass/AZO | 30 | 3.8 | 12 | — |
| Glass/Al₂O₃/AZO | 30 | 3.8 | 13.4 | 11.6 |
| Glass/AZO | 35 | 4 | 12.1 | — |
| Glass/Al2O3/AZO | 35 | 4 | 13.2 | 9.1 |

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method for forming a light-emitting device, the method comprising:
providing a substrate having a first refractive index;
coupling a transparent electrode to an organic layer, the transparent electrode having a second refractive index different from the first refractive index;
selecting an undercoat layer having a third refractive index to substantially match the first refractive index to the second refractive index; and
providing the undercoat layer between the substrate and the transparent electrode.

2. The method according to claim 1, wherein the organic layer emits light through the transparent electrode, and
the step of selecting the undercoat includes minimizing a reflection of the emitted light at an interface between the transparent electrode and the substrate.

3. The method according to claim 2, wherein the step of selecting the undercoat includes increasing an amount of light transmitted from the transparent electrode to the substrate.

4. The method according to claim 2, wherein the step of selecting the undercoat includes decreasing the resistivity of the transparent electrode.

5. The method according to claim 1, wherein the step of selecting an undercoat layer includes selecting a number of sub-layers to produce the third refractive index,
wherein the undercoat layer provided between the substrate and the transparent electrode includes the number of selected sub-layers.

6. The method according to claim 1, wherein the step of selecting the undercoat layer includes selecting the undercoat layer to reduce an iridescence of the transparent electrode.

7. The method according to claim 1, wherein the step of selecting the undercoat layer includes selecting the undercoat layer to reduce a sodium ion migration from the substrate to the transparent electrode.

8. A light-emitting device comprising:
a substrate having a first refractive index;
a transparent electrode coupled to an organic layer and disposed between the organic layer and the substrate, the transparent electrode having a second refractive index different from the first refractive index; and
an undercoat layer disposed between the substrate and the transparent electrode, the undercoat layer having a third refractive index,
wherein the undercoat layer is formed with the third refractive index such that the first refractive index is substantially matched to the second refractive index.

9. The light-emitting device according to claim 8, wherein the undercoat layer includes one or more sub-layers selected to form the third refractive index.

10. The light-emitting device according to claim 9, wherein the one or more sub-layers is formed using a same material.

11. The light-emitting device according to claim 8, wherein a material of the undercoat layer comprises at least one of silicon oxide, tin oxide, titanium oxide, aluminum oxide or zinc oxide.

12. The light-emitting device according to claim 8, wherein the substrate is formed from a transparent material.

13. The light-emitting device according to claim 12, wherein the material of the substrate comprises soda lime glass or borosilicate glass.

14. The light-emitting device according to claim 8, wherein a material of the transparent electrode comprises doped zinc oxide, indium tin oxide (ITO), indium zinc oxide (IZO), F-doped tin oxide or niobium-doped titanium dioxide.

15. The light-emitting device according to claim 8, further comprising a metal electrode disposed on the organic layer.

16. The light-emitting device according to claim 8, wherein the light-emitting device includes an organic light emitting diode (OLED).

17. A method for fabricating a light-emitting device, the method comprising:
forming an undercoat layer on a substrate by a first chemical vapor deposition (CVD) process;
forming a transparent electrode on the undercoat layer by a second chemical vapor deposition (CVD) process; and
forming an organic layer on the transparent electrode,
wherein the substrate has a first refractive index and the transparent electrode has a second refractive index different from the first refractive index, and
the undercoat layer is formed to have a third refractive index such that the first refractive index is substantially matched to the second refractive index.

18. The method according to claim 17, wherein the step of forming the undercoat layer includes forming one or more sub-layers by the chemical vapor deposition (CVD) process to form the third refractive index.

19. The method according to claim 17, wherein the chemical vapor deposition (CVD) process is performed at a temperature of 300° C. to 650° C.

20. The method according to claim 17, wherein the chemical vapor deposition (CVD) process is performed at atmospheric pressure.

21. The method according to claim 17, further including forming a metal electrode on the organic layer.
